(19) United States
(12) Patent Application Publication
(10) Pub. No.: US 2007/0085183 A1
(43) Pub. Date: Apr. 19, 2007

(54) INTEGRATED CIRCUIT

(75) Inventors: Tsutomu Takeya, Niigata-ken (JP); Shuichi Usami, Niigata-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/538,514

(22) Filed: Oct. 4, 2006

(30) Foreign Application Priority Data
Oct. 12, 2005 (JP) 2005-297821

(51) Int. Cl. H01L 23/02; H01L 21/00; H01L 31/0203

(52) U.S. Cl. 257/680; 257/434; 438/110; 438/112

(57) ABSTRACT

An integrated circuit is provided. The integrated circuit comprises a plurality of electrode pads that are exposed through openings of a surface protective layer. An NG identification marker is attached to the integrated circuit. An NG marker pad is separate from the plurality of electrode pads and exposed through an opening of the surface protective layer so as to specify a position at which the NG identification marker is placed.

This patent document claims the benefit of Japanese Patent Application No. 2005-297821 filed on Oct. 12, 2005, which is hereby incorporated by reference.

### BACKGROUND

1. Field

The present embodiments relate to an integrated circuit.

2. Related Art

Integrated circuits that are mounted on, for example, electric apparatuses have a plurality of circuit elements. After a plurality of integrated circuits are simultaneously formed on one wafer, the wafer is cut into individual integrated circuits. Before the wafer is cut, the integrated circuits are subject to an electrical characteristic test or an appearance test. When the integrated circuits do not meet predetermined specifications during the test, NG identification markers that indicate characteristic defects or appearance defects are attached to the surfaces of the integrated circuits.

The surface of each of the integration circuits is covered with a surface protective layer. The NG identification marker is attached to at least one among a plurality of electrode pads that are exposed through openings of the surface protective layer. The NG identification marker is coated on an entire surface of at least one electrode pad. After the wafer is cut, the quality of each of the integrated circuits is determined according to whether or not there is an NG identification marker.

The NG identification marker is formed of, for example, an ink. The NG identification marker is recognized by its luminance that is lower than the electrode pads and the contrast difference on the surface of the integrated circuit (a difference between the contrast difference between the surface protective layer and the electrode pads and the contrast difference between the surface protective layer and the NG identification marker). As a result, only the integrated circuits having superior quality are extracted and used as products (for example, see JP-A-2002-217252).

As electronic apparatuses gradually become smaller in size, pitch intervals of integrated circuits, which are formed on the wafer, are smaller, and the sizes of the respective integrated circuits are reduced. For this reason, in a state before the wafer is cut, when the above-described NG identification marker is coated on an electrode pad of an integrated circuit having a characteristic defect, the NG identification marker on the integrated circuit extends to adjacent integrated circuits. Therefore, even if the adjacent integrated circuits have no defects, the adjacent integrated circuits cannot be used. Thus, an integrated circuit that is capable of preventing displacement of an NG identification marker and generation of defects due to the displacement is desired.

### SUMMARY

In one embodiment, an integrated circuit includes a plurality of electrode pads that are exposed through openings of a surface protective layer. An NG identification marker is attached to the integrated circuit when the integrated circuit is defective. An NG marker pad is provided separate from the plurality of electrode pads and is exposed through an opening of the surface protective layer so as to specify a position at which the NG identification marker is placed.

In one embodiment, the NG marker pad may be a dummy pad that is not connected to wiring lines and the electrode pads in the integrated circuit.

In another embodiment, the plurality of electrode pads include an input electrode pad group at one end and an output electrode pad group at the other end in a widthwise direction of the integrated circuit that are disposed in parallel with each other in a lengthwise direction of the integrated circuit. In this embodiment, the NG marker pad may be positioned between the input electrode pad group and the output electrode pad group. According to this configuration, since wide intervals between the NG marker pad and the adjacent integrated circuits can be ensured, there is no concern that the NG marker is attached to the adjacent integrated circuits.

In one embodiment, the NG marker pad is formed of a metallic material. The surface protective layer is formed of a multilayer film having a Si oxide layer, a Si nitride layer, or a laminated layer thereof laminated on an antireflection layer. In one embodiment, the antireflection layer is made of Ti—N. In particular, the NG marker pad and the plurality of pads may be formed of the same metallic material, such that the NG marker and the plurality of electrode pads can be formed through the same process.

The integrated circuit having the above-described configuration can be applied to a driving circuit of a thermal head.

The NG marker pad, which is separated from the plurality of electrode pads, is formed, and specifies a position at which the NG recognition marker is placed. Accordingly, it is possible to avoid generation of defects in products due to displacement of the NG identification marker.

### BRIEF DESCRIPTION OF THE DRAWINGS

FIG. 1 is a schematic plan view that illustrates an exemplary thermal head that includes an integrated circuit;

FIG. 2 is a schematic cross-sectional view of an exemplary thermal head;

FIG. 3A illustrates a method of determining the quality of an integrated circuit, when an NG identification marker is not attached to a surface of the integrated circuit; and

FIG. 3B illustrates a method of determining the quality of an integrated circuit, when an NG identification marker is attached to the surface of the integrated circuit.

### DETAILED DESCRIPTION

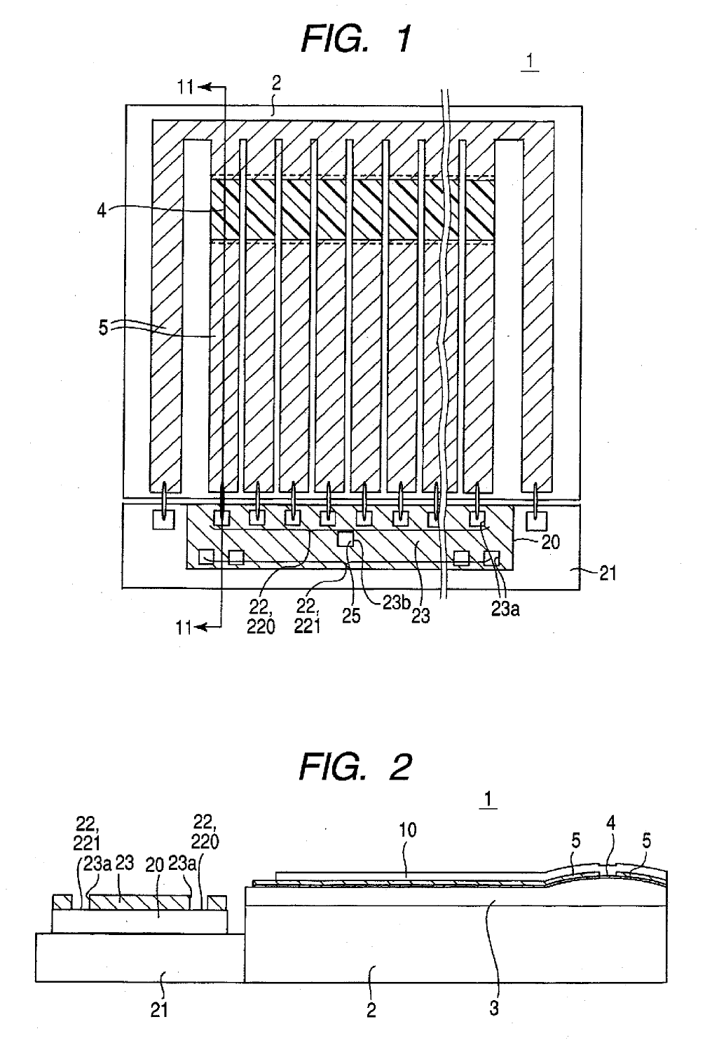

In one embodiment, as shown in FIG. 1 and FIG. 2, a thermal head 1 includes a head substrate 2 having a plurality of heating resistors 4 that generate heat when power is supplied thereto, and an integrated circuit 20 that controls power supply to the plurality of heating resistors 4.

The head substrate 2 includes a heat storage layer 3 that covers the substrate surface. The plurality of heating resistors 4 are formed on the heat storage layer 3 and arranged in a row at small intervals therebetween in a right and left direction of FIG. 1. An electrode layer 5 supplies power to the plurality of heating resistors 4. A wear resistant insulating layer 10 covers and protects the plurality of heating resistors 4 and the electrode layer 5.

The integrated circuit 20 is formed on an elongated bar-shaped substrate 21 that extends in the right and left direction of FIG. 1. The integrated circuit 20 includes a plurality of circuit elements having a plurality of switching elements that are provided to correspond to the plurality of heating resistors 4 on the head substrate 2. A plurality of electrode pads 22 connected to the integrated circuit 20, and a surface protective layer 23 covering and protecting the integrated circuit 20 are provided on the integrated circuit 20.

The surface protective layer 23 is a multilayer having a Si—O layer, a Si—N layer, or a laminated layer laminated on an antireflection layer that is formed of Ti—N. A plurality of first openings 23a having a rectangular shape are formed in the surface protective layer 23 so as to expose the plurality of electrode pads 22.

The plurality of electrode pads 22 include an input pad group 221 at one end and an output pad group 220 at the other end in a widthwise direction of the integrated circuit 20 (a top and bottom direction of FIG. 1) that are disposed in parallel with each other in a lengthwise direction of the integrated circuit 20 (the right and left direction of FIG. 1).

The input pad group 221 is an external connection terminal group that connects the integrated circuit 20 to an external electrical system, and supplies a signal from the outside to the integrated circuit 20. The output pad group 220 is an external connection terminal group that connects the switching elements of the integrated circuit 20 to the electrode layer 5 of the head substrate 2. The output pad group 220 is connected to the electrode layer 5 by wire bonding. As signals from the respective switching elements of the integrated circuit 20 are supplied to the corresponding plurality of heating resistors 4 through the output pad group 220 and the electrode layer 5, the plurality of heating resistors 4 are selectively turned on or off. The electrode pads 22 are formed of conductive materials, for example, Al, AlSiCu, or AlCu. The integrated circuit 20 according to this embodiment has dimensions of about 0.4 mm (widthwise direction)×10 mm (lengthwise direction), and has a thickness of about 0.3 mm.

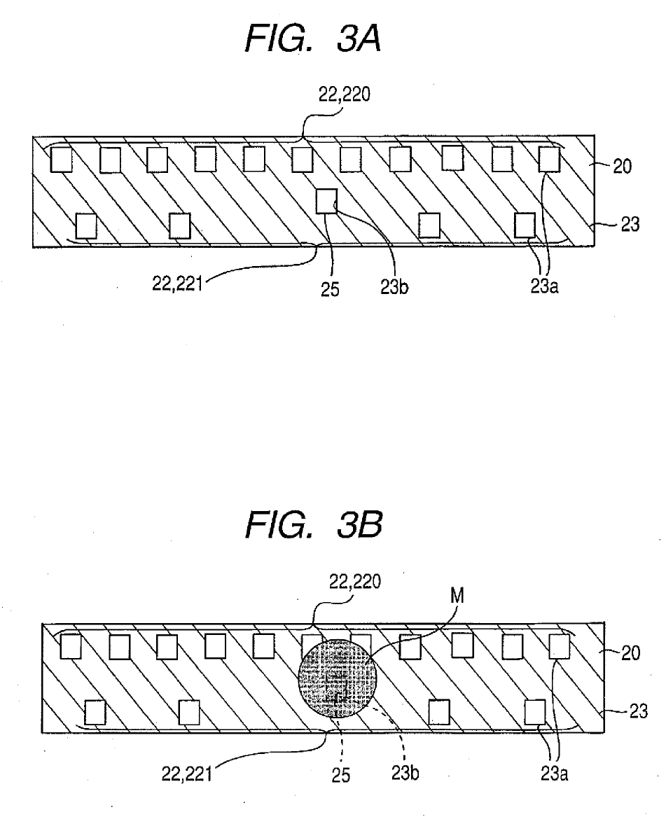

The integrated circuit 20 includes an NG marker pad 25 separate from the plurality of electrode pads 22, which specifies a position at which an NG identification marker M (FIG. 3B) is placed. The NG identification marker M is a marker for determining the quality, which is attached when it is determined by an appearance test or an electrical characteristic test that the integrated circuit has a defect. FIG. 3A illustrates the surface of the integrated circuit 20 when the NG identification marker M is not attached, and FIG. 3B illustrates the surface of the integrated circuit 20 when the NG identification marker M is attached.

The NG marker pad 25 between the input pad group 221 and the output pad group 220 is positioned at a central portion in the lengthwise direction of the integrated circuit 20. One second opening 23b is formed on the surface protective layer 23 such that the NG marker pad 25 is exposed in a rectangular shape.

The NG marker pad 25 is a dummy pad that is formed of the conductive material, for example, Al, AlSiCu, or AlCu. The dummy pad is not connected to wiring lines in the integrated circuit 20 and the plurality of electrode pads 22. The NG marker pad 25 and the plurality of electrode pads 22 are formed at the same time because they use the same conductive material. The NG marker pad 25 may be formed of another conductive material other than the conductive material for forming the plurality of electrode pads 22.

The NG identification marker M is formed of, for example, an ink that contains dyes or pigments. The NG identification marker M is darker (has lower luminance) than the surface of the integrated circuit 20 that includes the NG marker pad 25 and the plurality of electrode pads 22. Whether or not the NG identification marker M is attached to the integrated circuit 20 can be easily determined with high accuracy by an image processing device that detects the contrast difference on the surface of the integrated circuit 20.

In one embodiment, the integrated circuit 20 is manufactured according to the following sequence.

On one wafer, integrated circuits 20 and dummy pad portions, which are not connected to the wiring lines inside the integrated circuits 20, are formed on circuit forming areas that are previously set. In each of the circuit forming areas, wiring line ends of the integrated circuit 20 include an input end at one end and an output end at the other end in a widthwise direction of the circuit forming area that are disposed in parallel with each other in a lengthwise direction of the circuit forming area. The dummy pad portion is positioned between the input end portion and the output end portion of the integrated circuit 20. The dummy pad portion is disposed at the central portion in the lengthwise direction of the circuit forming area, for example, at the central portion of the circuit forming area.

The surface protective layer 23 is formed on the entire surface of the wafer that includes the plurality of integrated circuits 20. The surface protective layer 23, which is positioned on the wiring line end of each of the integrated circuits 20, is removed in a rectangular shape so as to form the first openings 23a. The wiring line end of the integrated circuit 20 is exposed through the plurality of first openings 23a. At the same time, for example, the surface protective layer 23 that is positioned on the dummy pad portion is removed in a rectangular shape so as to form the second opening 23b. The dummy pad portion is exposed through the second opening 23b. Therefore, the plurality of electrode pads 22 (i.e., the input pad group 221 and the output pad group 220) formed of the wiring line ends (i.e., the input end and the output end) from the exposed integrated circuit 20, and the NG marker pad 25 formed of the exposed dummy pad portion are obtained.

In one embodiment, an appearance test or an electrical characteristic test is performed on the plurality of integrated circuits 20 that are formed on the wafer. When the integrated circuit 20 does not satisfy predetermined specifications, the NG identification marker M is coated on the NG marker pad 25. As described above, since the NG marker pad 25 is disposed at the central portion of each of the circuit forming areas, the NG identification marker M does not extend to adjacent circuit forming areas when the NG identification marker M is attached to the NG marker pad 25. Little displacement of the NG identification marker M occurs.

After the test, the wafer is cut into individual integrated circuits 20 by the circuit forming areas.

The quality of each of the integrated circuits 20 is determined according to whether or not there is the NG identification marker M. This quality determination is performed while observing a still image on the surface of the integrated circuit 20, in particular, around the NG marker pad 25 by using a predetermined image processing device. As shown in FIG. 3B, when the NG identification marker M is attached, the NG marker pad 25 is coated with the NG identification marker M. The contrast difference (for example, the contrast difference between the surface protective layer 23 and the NG identification marker M) on the surface of the integrated circuit 20 is greater than a predetermined value. In this case, it is determined that there is the NG identification marker, for example, the integrated circuit 20 is defective. The contrast difference between the surface protective layer 23 and the NG identification marker M is large enough to facilitate the determination.

Alternatively, as shown in FIG. 3A, when the NG identification marker M is not attached, the NG marker pad 25 is exposed on the surface of the integrated circuit 20. Therefore, the contrast difference (the contrast difference between the surface protective layer 23 and the NG marker pad 25) on the surface of the integrated circuit 20 is smaller than the predetermined value. In this case, it is determined that there is no NG identification marker, for example, the integrated circuit 20 is of acceptable quality.

Only the integrated circuits 20 that are of acceptable quality are extracted and used as products.

In one embodiment, the integrated circuit 20 is provided with the NG marker pad 25 that specifies a position at which the NG identification marker M is placed. The NG identification marker M does not extend to another adjacent integrated circuits 20 when the NG identification marker M is coated on each of the integrated circuits 20 on the wafer. Accordingly, it is possible to avoid generation of defects in products that results from displacement of the NG identification marker M.

In one embodiment, there is provided the NG marker pad 25 formed of the dummy pad portion that is not connected to the wiring lines in the integrated circuit 20 and the plurality of electrode pads 22. However, the NG marker pad may be grounded. In this embodiment, the NG marker pad may be connected to a ground wiring line of the integrated circuit 20 so as to be grounded. Alternatively, the NG marker pad may be connected to an external ground potential point so as to be grounded.

As described above, the present embodiments are applied to the driving circuit of the thermal head has been described. However, the present embodiments can be applied to general integrated circuits. For example, when the invention can be applied to an integrated circuit whose substrate size is small and still achieve the desired results.

1. An integrated circuit comprising:
a plurality of electrode pads exposed through openings of a surface protective layer;
an NG marker pad separate from the plurality of electrode pads and exposed through an opening of the surface protective layer; and
an NG identification marker disposed at the NG marker pad.

2. The integrated circuit according to claim 1,
wherein the NG marker pad is not connected to wiring lines or the electrode pads.

3. The integrated circuit according to claim 1,
wherein the NG marker pad is grounded.

4. The integrated circuit according to claim 1,
wherein the plurality of electrode pads includes an input electrode pad group at one end and an output electrode pad group at the other end in a widthwise direction and disposed in parallel with each other in a lengthwise direction, and
the NG marker pad is positioned between the input electrode pad group and the output electrode pad group.

5. The integrated circuit according to claim 1,
wherein the NG marker pad is formed of a metallic material,
the surface protective layer is formed of a multilayer film comprising a Si oxide layer, a Si nitride layer, or a laminated layer, and
the surface protective layer is laminated on an antireflection layer.

6. The integrated circuit according to claim 5,
wherein the antireflection layer is formed of Ti—N.

7. The integrated circuit according to claim 5,
wherein the NG marker pad and the plurality of electrode pads are formed of the same metallic material.

8. The integrated circuit according to claim 1,
wherein the integrated circuit drives a thermal head.
